(19) United States
(12) Patent Application Publication
(10) Pub. No.: US 2005/0064609 A1
(43) Pub. Date: Mar. 24, 2005

(54) Semiconductor processing system

(75) Inventors: Hideki Nagaoka, Nirasaki-shi (JP); Aya Morokata, Nirasaki-shi (JP); Norikazu Sasaki, Nirasaki-shi (JP); Kazushige Shimura, Nirasaki-shi (JP); Kenetsu Mizusawa, Nirasaki-shi (JP); Akira Obi, Nirasaki-shi (JP); Masaaki Abe, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/968,895

(22) Filed: Oct. 21, 2004

Related U.S. Application Data
(63) Continuation-in-part of application No. PCT/JP03/04716, filed on Apr. 14, 2003.

(30) Foreign Application Priority Data
Apr. 22, 2002 (JP) 2002-119780
Jan. 7, 2003 (JP) 2003-001603

(51) Int. Cl. H01L 21/00; B05C 11/00

(52) U.S. Cl. 438/5; 118/712

(57) ABSTRACT

A semiconductor processing system includes a processing chamber, a gas exhaust unit, a gas supply unit, a flow rate controller, a flow rate measuring unit for inspecting the flow rate controller, and a control unit for controlling the processing system. The flow rate measuring unit contains an inspection vessel, a pressure gauge, and a flow rate calculation unit, and the control unit is configured to purge the inspection vessel before or after flowing the processing gas into thereto. Further, an inspecting method of the flow rate controller in the semiconductor processing system includes the steps of flowing the processing gas to the inspection vessel, detecting an inner pressure of the inspection vessel, obtaining a gas flow rate of the flow rate controller, and performing a purge process on the inspection vessel.

This application is a Continuation-In-Part of PCT International Application No. PCT/JP03/04716 filed on Apr. 14, 2003, which designated the United States.

### FIELD OF THE INVENTION

The present invention relates to a semiconductor processing system for performing a predetermined process on a substrate to be processed, e.g., a semiconductor wafer, and an inspecting method of a flow rate controller installed in the system. The term “semiconductor processing” used herein implies various processes to manufacture semiconductor devices and/or a structure including wiring, electrodes, and the like connected to the semiconductor devices on a substrate to be processed, by forming a semiconductor layer, an insulating layer, a conductor layer, and the like, in a predetermined pattern, on the substrate to be processed, e.g., a semiconductor wafer or an LCD substrate.

### BACKGROUND OF THE INVENTION

In order to form an integrated circuit (IC) on a substrate to be processed, e.g., a semiconductor wafer, an LCD substrate, or the like, various kinds of semiconductor processes such as a film forming process in a processing apparatus, an etching process, an oxidation/diffusion process, a sputtering, and the like, are repeatedly performed on the substrate to be processed. Accordingly, the substrate to be processed inside a processing chamber of the processing apparatus is subject to heating or cooling, to thereby be maintained at a specific process temperature. Further, an inside of the processing chamber is maintained at a specific process pressure by exhausting an atmosphere inside the processing chamber while introducing a processing gas into the processing chamber.

A processing gas flow rate has a significant impact on the semiconductor process, e.g., the film forming or the like. For performing a very accurate process as designed, the flow rate of the processing gas supplied into the processing chamber should be precisely controlled. Thus, a very accurate flow rate controller such as a mass flow controller, which is provided for each processing gas individually, is employed.

The flow rate controller of a high accuracy in a flow rate controllability needs to be replaced in case when the flow rate controllability is changed a little due to aging, or there is a failure. Accordingly, a regular or an irregular inspection is performed to determine whether or not the flow rate controller accurately flows a gas at a current flow rate as instructed.

Such an inspection of the flow rate controller is performed by flowing a processing gas into the processing chamber at a specific flow rate instructed for the inspection while an exhaust valve of the processing chamber is closed. At this time, an actual gas flow rate is obtained, based on a pressure rising rate inside the processing chamber and an exact inner volume of the processing chamber, which was measured at the time of a factory shipment. Further, it is determined whether or not the actual gas flow rate obtained coincides with the flow rate instructed for the inspection. By doing this, the controllability of the flow rate controller can be determined.

Meanwhile, the inner volume of the processing chamber may be changed due to any replacements of various structures inside the processing chamber with different shape (volume) of structures during a long-term use of the processing apparatus. In this case, it is difficult to estimate an exact volume of the processing chamber. Further, a temperature inside the processing chamber has to be adjusted to a process temperature that depends on a process when inspecting, but it is very troublesome work to raise or lower the temperature inside the processing chamber for every process.

For resolving the aforementioned problem, there has been known an inspecting method of using an inspection vessel of a known volume, which is disposed on a bypass line between a gas supply line system and an exhaust line system of the processing chamber. In this case, the inspection of a flow rate controller is performed by introducing a gas into the inspection vessel instead of flowing the gas into the processing chamber. As described above, an actual gas flow rate is obtained based on the pressure rising rate inside the processing vessel and the like to thereby determine the controllability of the flow rate controller.

In case of actually inspecting a flow rate controller, inspections are sequentially conducted on a plurality of flow rate controllers that are installed in the processing apparatus. If a processing gas used for a prior inspection is left in the inspection vessel, a residual gas in the inspection vessel will be combined with a processing gas to be introduced for a subsequent inspection, thereby resulting in following problems. Particularly, in case where a prior inspection has been terminated abnormally due to an error or the like, the processing gas is likely to be left in the inspection vessel, thereby causing the following problems.

For example, these two gases may violently react with each other. To be more specific, if the residual gas is H₂ gas and the gas to be introduced is O₂ gas, it is very likely to damage the inspection vessel by a violent combustion. Further, the two gases may react with each other to produce a corrosion gas. For example, if the residual gas is H₂ gas and the gas to be introduced is Cl₂ gas, a corrosion gas (HCl) is produced by a reaction therebetween, whereby the apparatus will be eroded.

### SUMMARY OF THE INVENTION

It is, therefore, an object of the present invention to provide a semiconductor processing system and an inspecting method of a flow rate controller capable of properly inspecting the flow rate controller while preventing any problems causing a failure such as damage or erosion of components.

In accordance with one aspect of the present invention, there is provided a semiconductor processing system, including: a processing chamber for accommodating therein a substrate to be processed; a gas exhaust unit, connected to the processing chamber through a gas exhaust line, for exhausting the processing chamber; a gas supply unit, connected to the processing chamber through a gas supply line, for supplying a processing gas into the processing chamber; a flow rate controller, disposed on the gas supply line, for controlling a flow rate of the processing gas; a flow rate measuring unit for inspecting the flow rate controller; and a control unit for controlling the processing system, wherein the flow rate measuring unit contains: an inspection vessel having a predetermined volume and placed on a gas bypass line connecting the gas supply line with the gas exhaust line to bypass the processing chamber; a pressure gauge for detecting an inner pressure of the inspection vessel; and a flow rate calculation unit for obtaining a gas flow rate of the flow rate controller based on a rising rate of a detection value from the pressure gauge, and wherein the control unit is configured to purge the inspection vessel by flowing a nonreactive gas to the inspection vessel before or after flowing the processing gas thereto.

In accordance with another aspect of the present invention, there is provided an inspecting method of a flow rate controller in a semiconductor processing system having a processing chamber for accommodating therein a substrate to be processed; a gas exhaust unit, connected to the processing chamber through a gas exhaust line, for exhausting the processing chamber; a gas supply unit, connected to the processing chamber through a gas supply line, for supplying a processing gas into the processing chamber; and a flow rate controller, disposed on the gas supply line, for controlling a flow rate of the processing gas, the method including the steps of: flowing the processing gas, whose flow rate is controlled by the flow rate controller, to an inspection vessel having a predetermined volume while a gas exhaust side thereof is closed, wherein the inspection vessel is disposed on a gas bypass line connecting the gas supply line with the gas exhaust line to bypass the processing chamber; detecting an inner pressure of the inspection vessel; obtaining a gas flow rate of the flow rate controller by a calculation based on a rising rate of a detected pressure; and performing a purge process on the inspection vessel by flowing to the inspection vessel a nonreactive gas before or after flowing the processing gas thereto.

In accordance with still another aspect of the present invention, there is provided a semiconductor processing system, including: a processing chamber for accommodating therein a substrate to be processed; a gas exhaust unit, connected to the processing chamber through a gas exhaust line, for exhausting the processing chamber; a gas supply unit, connected to the processing chamber through a gas supply line, for supplying a processing gas into the processing chamber; a flow rate controller, disposed on the gas supply line, for controlling a flow rate of the processing gas; a pressure gauge for detecting an inner pressure of the processing chamber; a flow rate calculation unit for obtaining a gas flow rate of the flow rate controller based on a rising rate of a detection value from the pressure gauge; and a control unit for controlling the processing system, wherein the control unit performs a correction operation by using an actually measured flow rate initially obtained by the flow rate calculation unit for a predetermined set flow rate as an initially measured reference flow rate, subsequently, calculates the difference between an actual flow rate subsequently measured by the flow rate calculation unit for the predetermined set flow rate and the initially measured reference flow rate, and declares an abnormal state where the difference falls outside a predetermined range.

### BRIEF DESCRIPTION OF THE DRAWINGS

The above and other objects and features of the present invention will become apparent from the following description of preferred embodiments given in conjunction with the accompanying drawings, in which:

FIG. 1 is a block diagram showing a semiconductor processing system including a processing apparatus and a flow rate measuring device, in accordance with a first embodiment of the present invention;

FIG. 2 offers a graph for showing a relationship between a gas flow rate and a pressure rising rate inside an inspection vessel in the system described in FIG. 1;

FIG. 3 describes processes for inspecting a flow rate controller in the system shown in FIG. 1;

FIGS. 4A and 4B set forth to flowcharts for showing an inspecting method of a flow rate controller in the system described in FIG. 1;

FIG. 5 is a typical view for showing two flow rate controllers each having an individual variation in the system described in FIG. 1;

FIG. 6 explains an example of an individual variation on characteristic of a flow rate controller for each maker, in the system shown in FIG. 1;

FIG. 7 provides a flowchart showing a modified example of the method shown in FIGS. 4A and 4B;

FIG. 8 is a block diagram showing a semiconductor processing system including a processing apparatus and a flow rate measuring device, in accordance with a second embodiment of the present invention;

FIG. 9 describes a block diagram showing a semiconductor processing system including a processing apparatus and a flow rate measuring device, in accordance with a third embodiment of the present invention;

FIGS. 10A and 10B are block diagrams for showing a flow rate measuring device and a housing for accommodating the flow rate measuring device, respectively, in the system described in FIG. 9;

FIG. 11 offers a schematic diagram for showing an outer appearance of the flow rate measuring device in the system described in FIG. 9;

FIG. 12 describes a flowchart for showing an attachment of the flow rate measuring device and a measured flow rate thereof, in the system shown in FIG. 9;

FIG. 13 is a flowchart for showing a detachment flow of the flow rate measuring device, in the system described in FIG. 9;

FIG. 14 provides a flowchart for explaining an initial flow rate correction operation for obtaining an initially measured reference flow rate, in the systems shown in FIGS. 1, 8, and 9;

FIGS. 15A and 15B are flowcharts for explaining a conventional flow rate correction operation after determining an initially measured reference flow rate, in the systems shown in FIGS. 1, 8, and 9;

FIG. 16 offers characteristic curves for showing a relationship between a set flow rate obtained by the calculation shown in FIGS. 15A and 15B and an actually measured flow rate; and

FIG. 17 is a time chart for showing a case where a sampling interval determination operation and an actual measurement operation are consecutively carried out.

### DETAILED DESCRIPTION OF THE PREFERRED EMBODIMENTS

Hereinafter, preferred embodiments of the present invention will be described in detail with reference to the accompanying drawings. Further, like reference numerals will be assigned to like parts having substantially same functions, and redundant description thereof will be omitted in the specification and the accompanying drawings.

First Embodiment

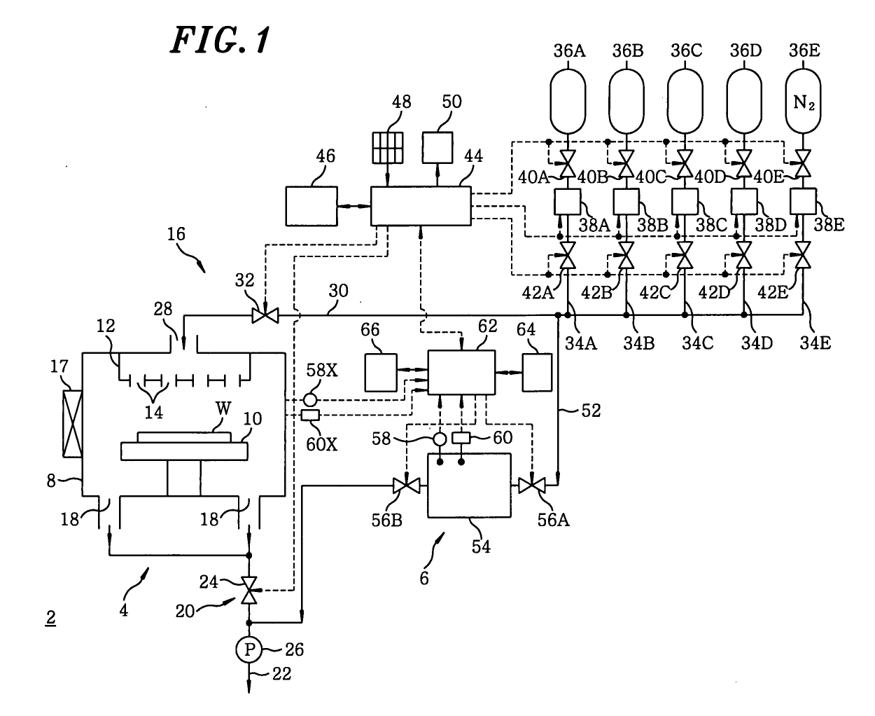

FIG. 1 is a block diagram showing a semiconductor processing system including a processing apparatus and a flow rate measuring device, in accordance with a first embodiment of the present invention. As shown in FIG. 1, a processing system 2 includes a processing apparatus 4 for performing a predetermined semiconductor process on a substrate to be processed, e.g., a semiconductor wafer, under the presence of a processing gas. Further, the processing system 2 includes a flow rate measuring device 6 for performing a flow rate inspection on a flow rate controller such as a mass flow controller that will be discussed later.

The processing apparatus 4 includes, e.g., a single wafer processing apparatus, and has a processing chamber 8 formed in a tube shape. Inside the processing chamber 8, a mounting table 10 for mounting the substrate to be processed, e.g., the semiconductor wafer W, is disposed. A heater (not shown) and the like are disposed in the mounting table 10. Further, on a ceiling of the processing chamber 8, there is installed a shower head 12 for introducing a required processing gas or a nonreactive gas such as N₂ gas into the inside of the processing chamber 8. A plurality of gas injection holes 14 are punched on a bottom surface of the shower head 12. A gas supply line system 16 for supplying a required gas is connected to the shower head 12. On a sidewall of the processing chamber 8, there is installed a gate valve 17, which is opened and/or closed when loading and/or unloading the wafer W into and/or from the processing chamber 8.

A gas exhaust port 18 is formed in a bottom portion of the processing chamber 8, and connected to a gas exhaust unit so as to exhaust the processing chamber 8 to a vacuum via a gas exhaust line system 20. The gas exhaust line system 20 is connected to the gas exhaust port 18 and has a gas exhaust line 22 in which an exhaust valve 24 is installed. To the gas exhaust line 22, there are connected the gas exhaust unit having a vacuum pump 26, a pressure adjusting valve (not shown), and the like.

The gas supply line system 16 is connected to an opening 28 of the shower head 12, and has a gas supply line 30 in which a supply valve 32 is installed. An upstream side of the gas supply line 30 is divided into multiple branch lines, e.g., five branch lines 34A to 34E in FIG. 1. The branch lines 34A to 34E are connected to gas sources 36A to 36E storing different kinds of gases, respectively. In the branch lines 34A to 34E, there are installed respective flow rate controllers 38A to 38E, e.g., mass flow controllers, for accurately controlling respective gas flow rates running therethrough. Upstream valves 40A to 40E and downstream valves 42A to 42E are placed in just upstream and downstream sides of the flow rate controllers 38A to 38E, respectively. By such a configuration, opening and stopping of each gas supply can be controlled independently.

Whole operations of the processing apparatus 4 containing opening/closing calculations of the valves 24, 32, 40A to 40E, and 42A to 42E, and gas flow rate set values of the flow rate controllers 38A to 38E are controlled by a main control unit 44 including, e.g., a micro computer and the like. To the system control unit 44, there are connected a memory 46 such as ROM for storing required information, an input unit 48 having a keyboard and the like for inputting various information or instructions, a display unit 50 displaying required information, and the like.

Here, for easy understanding of the present invention, all the gas sources 36A to 36E are connected to a single gas supply line 30. However, in reality, multiple gas supply lines may be installed depending on the kind of process, and connected to the respective gas sources. When inspecting the flow rate controller, each gas selectively flows towards the flow rate measuring device 6 by the opening/closing operations of the valve.

Meanwhile, a bypass line 52 is installed such that a portion of the gas supply line 30 corresponding to an upstream of the supply valve 32 is connected to a portion of the gas exhaust line 22 between the gas exhaust valve 24 and a vacuum pump. The flow rate measuring device 6 contains a hollow inspection vessel 54 having an accurately pre-measured known inner volume, and is disposed on the bypass line 52. As the flow rate measuring device 6, MKS instruments, Inc. GBROR (registered trademark) may be used, for example. The inspection vessel 54 is made of, e.g., aluminum or the like. The known volume Vo may be set at, e.g., 1000 cm³.

In an upstream side and a downstream side bypass line 52 of the inspection vessel 54, there are installed an upstream valve 56A and a downstream valve 56B, whose opening and closing operations can be controlled independently. A pressure gauge 58 such as a volume manometer for detecting an inner pressure thereof and a temperature gauge 60 for measuring an inner temperature thereof are equipped in the inspection vessel 54. Measurement values obtained (detection value) through the pressure gauge 58 and the temperature gauge 60 are inputted to a flow rate measurement control unit 62 including, e.g., a micro computer and the like, for controlling whole operations of the flow rate measuring device 6. Further, respective opening and closing operations of the valves 56A and 56B may be performed not by the flow rate measurement control unit 62 but by the main control unit 44.

To the flow rate measurement control unit 62, there are connected a flow rate calculation unit 64 for obtaining a gas flow rate based on a rising rate of the detection value by the pressure gauge 58, and a memory 66 such as ROM capable of storing required information. In fact, a function of the flow rate calculation unit 64 is processed by software in a central operation processing unit contained in the flow rate measurement control unit 62. The flow rate measuring device 6 functions to send (receive) various information to (from) the main control unit 44 under the control of the main control unit 44. In the flow rate measuring device 6, a flow rate measuring operation itself is carried out by an instruction from the flow rate measurement control unit 62.

Next, an inspecting method of the flow rate controller, which is carried out in the semiconductor processing system 2 having such a configuration, will be discussed. When performing a conventional process on the semiconductor wafer W, the upstream and the downstream valve 56A and 56B of the flow rate measuring device 6, which are installed on the bypass line 52, are closed. Accordingly, the flow rate measuring device 6 is isolated to prevent a gas from flowing thereto.

Meanwhile, it is checked regularly or irregularly whether or not each of the flow rate controllers 38A to 38E accurately flows a gas at a normal gas flow rate. In this case, the supply valve 32 placed on the gas supply line 30 and the exhaust valve 24 placed on the gas exhaust line 22 are closed, in contrast with the aforementioned conventional process. Thus, the processing chamber 8 is isolated to prevent a gas from flowing thereto. Further, as explained below, it is checked whether or not the gas runs through at a normal gas flow rate by flowing a gas towards the inspection vessel 54.

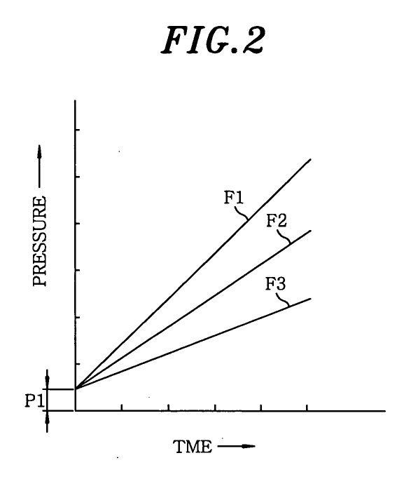

FIG. 2 is a graph for showing a relationship between a pressure rising rate inside the inspection vessel 54 and a gas flow rate. In FIG. 2, reference numeral P1 indicates a base pressure inside the inspection vessel 54, i.e., a pressure before flowing a gas. Further, there are shown characteristic curves having three kinds of gas flow rates, e.g., F1 sccm, F2 sccm, and F3 sccm. It is natural that these gas flow rates have such a relation, i.e., F1>F2>F3. If a constant flow rate of gas is supplied into the inspection vessel 54 while the exhaust valve 56B is closed, an inner pressure of the inspection vessel 54 increases linearly and proportionally. By calculating a rising rate at that time, a gas flow rate can be obtained.

In order to improve an accuracy of a measurement value for the gas flow rate, a volume Vo inside the inspection vessel 54 has been measured and known. Further, volumes inside the lines have been measured and known, wherein the lines are of the bypass line 52, the gas supply line 30, and each of the branch lines 34A to 34E that are connected to respective flow rate controllers 38A to 38E. Each of the volume values is pre-stored in the memory 66 of the flow rate measuring device 6. While the inspection vessel 54 is set at a room temperature, an inner pressure of a sealed space is proportional to an absolute temperature. As a result, a temperature inside the inspection vessel 54 is exactly detected by the temperature gauge 60 and is compensated when calculating a gas flow rate.

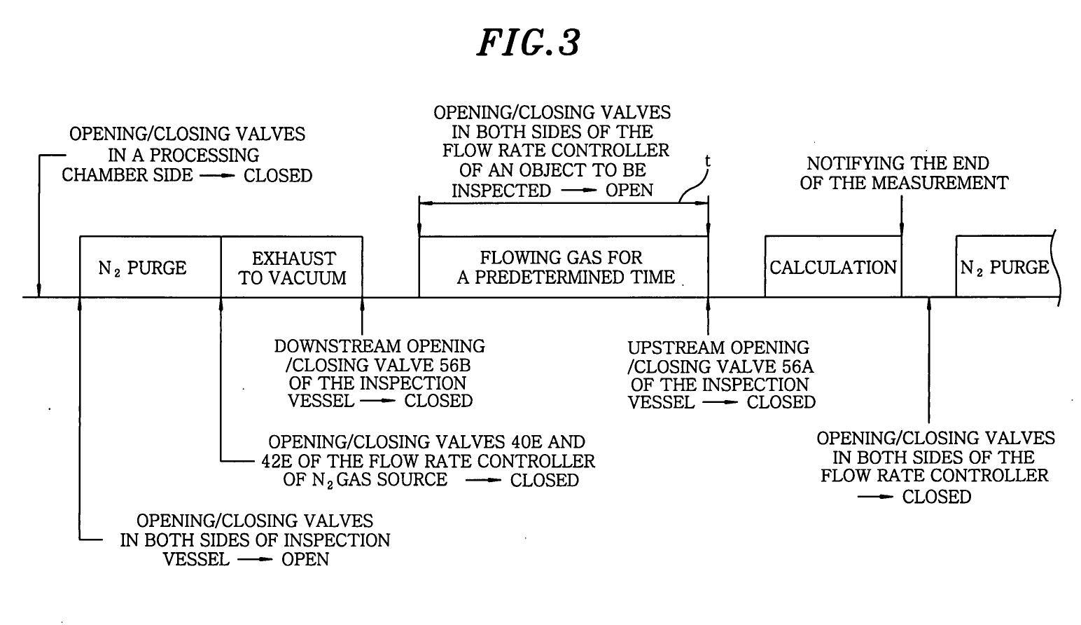

FIG. 3 shows operation processes for inspecting the flow rate controller, which are performed under the controls of the main control unit 44 and the flow rate measurement control unit 62. An inspecting method will be discussed below with reference to FIG. 3. Here, as a nonreactive gas, N₂ gas may be stored in the gas source 36E shown in FIG. 1, for example. Instead of N₂ gas, Ar gas or He gas may be used. Further, in the following explanation, each operation is performed under the control of the main control unit 44 as long as it is not clearly referred that an operation is performed under the control of the flow rate measurement control unit 62. However, in the present invention, each of the operations is not necessarily controlled by the main control unit 44 and the flow rate measurement control unit 62, individually, but it can be controlled by both of them.

As shown in FIG. 3, the valves 24 and 32 of the processing chamber 8 side are closed to prevent a gas from flowing towards the processing chamber 8. Then, the valves 56A and 56B in both sides of the inspection vessel 54 of the flow rate measuring device 6 are opened. In such a state, an atmosphere inside the inspection vessel 54 is purged by flowing N₂ gas from the gas source 36E. Thereafter, the valves 40E and 42E of the N₂ gas source 36E are closed to stop supplying the N₂ gas. Further, by continuously operating the vacuum pump 26, an inside of the inspection vessel 54 or the line is exhausted to vacuum.

Subsequently, the downstream (outlet) valve 56B of the inspection vessel 54 is closed and, at the same time, the valves in both sides of the flow rate controller corresponding to an object to be inspected are opened. Accordingly, a gas from the gas source is supplied into the inspection vessel 54 at a predetermined set flow rate and flows thereto. Here, it is assumed that a flow rate controller of an object to be inspected is the flow rate controller 38A connected to the gas source 36A. In this case, both sides of the valves 40A and 42A are opened and a gas stored in the gas source 36A is supplied into the inspection vessel 54. At this time, an inner pressure of the inspection vessel 54 is continuously detected by the pressure gauge 58, and linearly increases, as shown in FIG. 2.

After flowing the gas at a predetermined set flow rate for a predetermined time t, the upstream valve 56A of the inspection vessel 54 is closed by the flow rate measurement control unit 62, which operates in a fully automated manner, to thereby stop supplying the gas into the inspection vessel 54. Here, the predetermined time t depends on an inspecting gas flow rate, and it is in the range from, e.g., about several tens of seconds to about several minutes. An actual gas flow rate (also referred to as a measurement flow rate) is obtained by a calculation of the flow rate calculation unit 64, based on a pressure rising rate, a volume Vo of the inspection vessel 54, and the like. At this time, temperature calibration is carried out, as mentioned above.

If a calculation result is obtained, the flow rate measurement control unit 62 notifies the main control unit 44 of the processing apparatus 4 that the gas flow rate measurement is completed and informs of a gas flow rate corresponding to the calculation result thereof. In response, the valves 40A and 42A in both sides of the flow rate controller 38A are closed by the main control unit 44. Further, the gas supply into the inspection vessel 54 is stopped before the upstream valve 56A is closed.

The main control unit 44 functions to display, e.g., in a display unit 50 an actual gas flow rate obtained by the calculation, and a gas flow rate (hereinafter, also referred to as a set flow rate) instructed for the flow rate controller 38A. The operator recognizes a difference between the two gas flow rates, to thereby determine a reliability of the flow rate controller 38A. Further, it can be configured such that the main control unit 44 determines the reliability thereof in a completely automated manner to display the result.

As described above, if the inspection for one flow rate controller 38A is completed, the aforementioned processes are sequentially performed on other flow rate controllers 38B to 38E. When performing an inspection on a subsequent flow rate controller, a N₂ purge process for flowing N₂ gas into the inspection vessel 54 is performed first, even in case where a measurement operation is interrupted due to an error or the like. By doing this, there will be no processing gas (except N₂ gas) left in the inspection vessel 54. Therefore, even though a processing gas for a subsequent inspection is introduced, there will be no sudden explosive reaction or a corrosion gas producing reaction. Further, the actual gas flow rate measured above is stored in the main control unit 44, and becomes a reference for controlling each of the flow rate controllers 38A to 38E when performing an actual process.

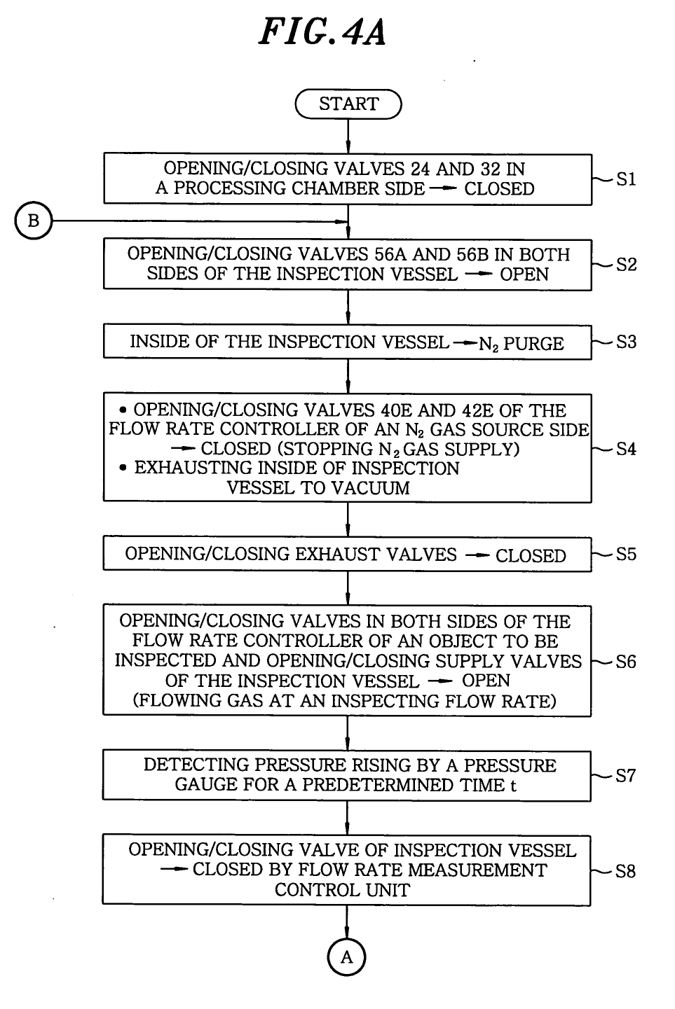

FIGS. 4A and 4B are flowcharts for showing an inspecting method of a flow rate controller. The above-described operations will be explained more specifically by using the flowcharts described in FIGS. 4A and 4B.

First, the operator inputs into the main control unit 44 an instruction for flow rate measurements on the flow rate controllers 38A to 38E. By the main control unit 44, both of the supply valve 32 and the exhaust valve 24 of the processing chamber 8 are closed to prevent the gas from flowing into the processing chamber 8. Further, at the same time, starting of a flow rate measurement is instructed to the flow rate measurement control unit 62 of the flow rate measuring device 6 (step S1).

Subsequently, the valves 56A and 56B in both sides of the inspection vessel 54 are opened by the flow rate measurement control unit 62 (step S2). Further, N₂ gas from the gas source 36E is introduced into the inspection vessel 54 to perform an N₂ purge, and a residual gas is discharged from the inspection vessel 54 (step S3). Especially, in case when an inspection is interrupted due to an error or the like, or forced to be stopped by the operator during the inspection, and then, the inspection is resumed again, the N₂ purge has to be performed before actually flowing a processing gas. Accordingly, it is possible to prevent in advance the residual gas in the inspection vessel 54 from reacting with a gas to be newly introduced.

Next, the valves 40E and 42E of the N₂ gas source 36E side are closed to stop supplying the N₂ gas. At the same time, the insides of the inspection vessel 54 and the downstream side of the flow rate controller 38E are exhausted to vacuum by continuously operating the vacuum pump 26 (step S4).

After exhausting to vacuum is completed, a valve 56B in an immediate downstream side of the inspection vessel 54 is closed (step S5). Further, the valves 40A and 42A in both sides of a flow rate controller of an object to be inspected, e.g., the flow rate controller 38A, are opened, and the valve 56A in an immediate upstream side of the inspection vessel 54 is opened. Therefore, a processing gas from the gas source 36A is introduced into the inspection vessel 54 and stored therein. Here, a flow rate control is performed by the flow rate controller 38A to maintain a gas flow rate instructed from the main control unit 44 (step S6).

At this time, an inner pressure of the inspection vessel 54 is detected by the pressure gauge 58 at all time. The pressure increases linearly, and is continuously detected for a predetermined time t (step S7). If the pressure detection for the predetermined time t is ended, the upstream valve 56A of the inspection vessel 54 is closed to stop supplying the processing gas from the gas source 36A into the inspection vessel 54 by the flow rate measurement control unit 62 (step S8).

Next, an actual gas flow rate is obtained by a calculation performed at the flow rate calculation unit 64 based on a pressure rising rate, a volume Vo of the inspection vessel 54, which has been stored in the memory 66 in advance, and volumes (stored in the memory 66 in advance) of the lines that are connected to the flow rate controller 38A (step S9). If a calculation result is obtained from such a calculation, the completion of the measurement is notified to the main control unit 44 by the flow rate measurement control unit 62 (step S10). Further, an instruction for an actual gas flow rate obtained as the calculation result is also sent thereto (step S11).

The valves 40A and 42A in both sides of the flow rate controller 38A, which is an object to be inspected, are closed by the main control unit 44 which has received such an instruction (step S12). Further, as described above, since the upstream valve 56A of the inspection vessel 54 has already been closed, the processing gas supply into the inspection vessel 54 is stopped.

At the same time, the actual gas flow rate obtained from the calculation result and the gas flow rate instructed for the flow rate controller 38A are displayed in, e.g., a display unit 50 by the main control unit 44 (step S13). The operator recognizes a difference between the two gas flow rates from the display unit 50, and determines the reliability of the flow rate controller 38A. Further, it can be configured such that the main control unit 44 determines the reliability in a fully automated manner and displays the result.

If the inspection for one flow rate controller is completed, it is confirmed whether or not there is another flow rate controller to be inspected present (step S14). If there is another controller present, the aforementioned processes are repeatedly carried out by returning to step S2, and inspections are performed on all the flow rate controllers 38A to 38E. Further, it can be configured such that the inspections are performed on one flow rate controller while changing a gas flow rate.

In the aforementioned operation, an N₂ gas purge is carried out before flowing the processing gas, when starting the inspection for each flow rate controller. Alternatively, the N₂ gas purge may be carried out right after flowing the processing gas. If the inspection is forced to be stopped by an error or the operator, the processing gas remains in the inspection vessel 54. In this case, the N₂ gas purge is performed right before flowing the processing gas again.

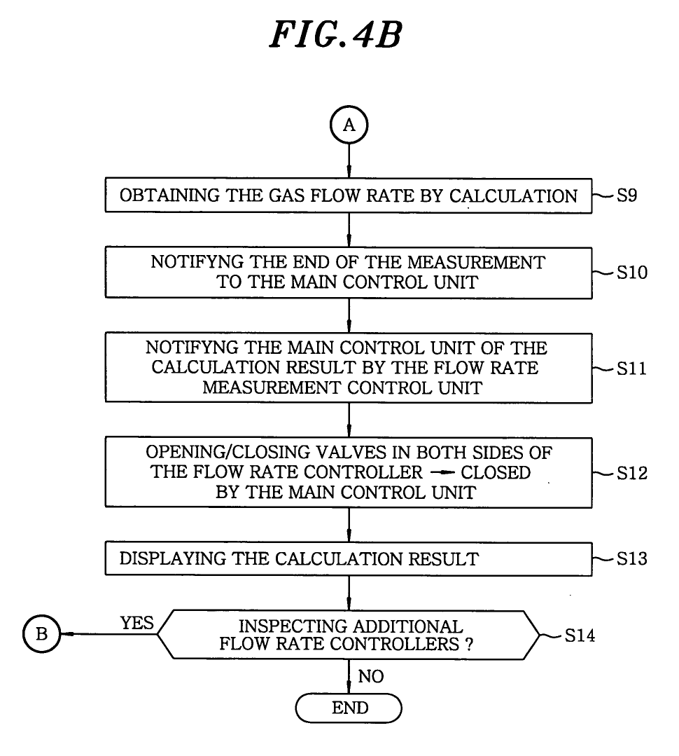

A flow rate controller has an individual variation and, particularly, a characteristic thereof may largely depend on a maker. FIG. 5 typically shows two flow rate controllers 38A and 38B, each having an individual variation, for example. Here, there is a difference between actual lengths L1 and L2 of the branch lines 34A and 34B, which are connected from the flow rate controller 38A and 38B to the downstream valves 42A and 42B, respectively. A difference in volumes corresponding to the length parts slightly affects a pressure rising rate in the inspection vessel 54. As a result, there may be a subtle shift in a calculated gas flow rate.

Thus, the volumes of the lengths L1 and L2 parts are pre-stored in the memory 66 of the flow rate measuring device 6 as volume correction coefficients for the flow rate controllers. Further, when calculating the gas flow rate, volumes of the lengths L1 and L2 parts are added. Accordingly, it is possible to obtain a more appropriate gas flow rate with a high accuracy.

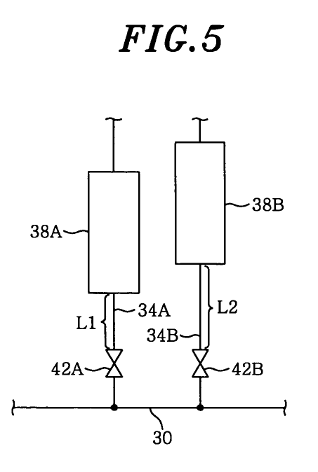

As described above, a flow rate controller may have an individual variation on characteristic, particularly, depending on a maker. FIG. 6 explains an example of an individual variation of a flow rate controller on characteristic for maker. For example, in a characteristic curve A of A company for a flow rate instruction value, an offset value is b1 and a slope a1 is smaller than that of a reference line Rref. Further, in a characteristic curve B of B company, an offset value is b2 and a slope a2 is larger than that of the reference line Rref. For example, even though a gas flow rate of 500 sccm is notified, 499 sccm and 501 sccm of gas flow rates are shown in A and B company's flow rate controllers, respectively.

In this case, a correction value of individual variation for each flow rate controller, e.g., for a maker is pre-stored in the memory 46 connected to the main control unit 44 such that each of the offset values b1 and b2 and each of the slopes a1 and a2 coincide with those of the reference line Rref. Further, the gas flow rate of the calculation result instructed from the flow rate measuring device 6 is compensated by using the correction value of individual variation. By this, it is possible to remove a deviation of the calculation result, due to, particularly, an individual variation that is likely to be generated for a maker of the flow rate controller, whereby reliability of the measurement result can be enhanced.

Here, it should be noted that obtaining an absolutely exact gas flow rate is very difficult and nearly impossible actually. Thus, obtaining the same calculation result in the end becomes an object, regardless of an individual variation for the flow rate controller, given that a characteristic of the flow rate controller is not deteriorated when flowing a gas under the same condition, e.g., the same instruction value of the gas flow rate.

The flow rate measuring device 6 of the present embodiment operates in a fully automated manner, and thus, closes the upstream valve 56A right after introducing a processing gas into the inspection vessel 54 for a predetermined time t (see FIG. 3). After carrying out the calculation, if the completion of the measurement is notified to the main control unit 44, the valves 40A and 42A in both sides of a flow rate controller corresponding to an object to be inspected, e.g., the flow rate controller 38A, are closed by the main control unit 44, to prevent a gas from flowing thereto. Thus, the gas is introduced not into the inspection vessel 54, but into a line placed in an upstream side of the upstream valve 56A, during the calculation in the flow rate calculation unit 64. In this case, there is a concern for leak of the processing gas in case where an inner pressure of the line placed in the upstream side is very high, e.g., higher than an atmospheric pressure, depending on an inspecting flow rate to be set.

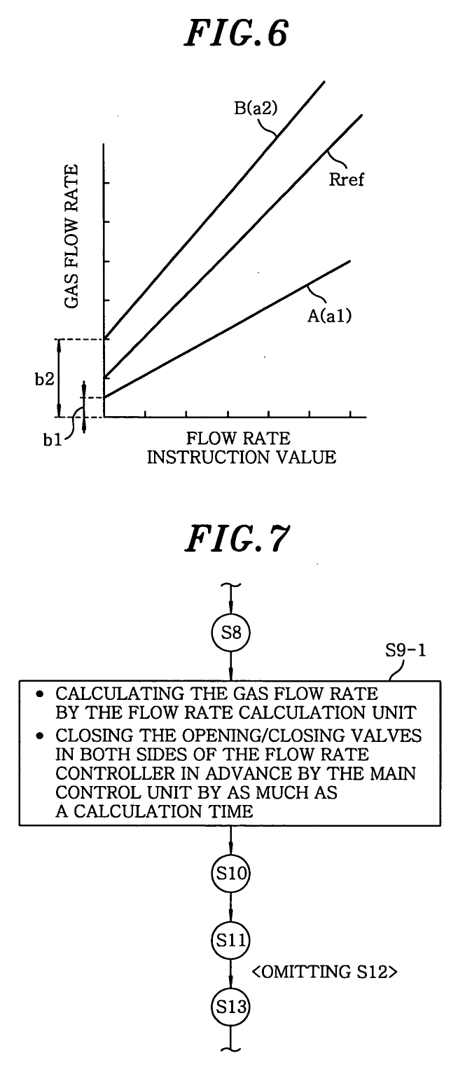

Therefore, it can be configured such that supplying the processing gas into a flow rate measuring unit may be stopped in advance by as much as a calculation time of the flow rate calculation unit. Namely, the main control unit can be configured to close the valves in both sides of the flow rate controller earlier than a time when receiving a measurement end signal from the flow rate measuring device 6. From this point of view, FIG. 7 offers a flowchart for showing an inspecting method of a flow rate controller in accordance with a modified example of the method described in FIGS. 4A and 4B. The method of the modified example is the same as those in the flowcharts shown in FIGS. 4A and 4B, except a part shown in FIG. 7.

Namely, the upstream valve 56A is closed by the flow rate measurement control unit 62 after a gas is introduced for a predetermined time t, in step S8. Then, a calculation of a gas flow rate is performed by the flow rate calculation unit 64 and, at the same time, the valves 40B and 42A in both sides of the flow rate controller 38A of an object to be inspected are closed by the main control unit 44 (step S9-1). Here, steps S9 and S12 in FIG. 4B are almost simultaneously carried out together. At this time, a time needed for the calculation is, e.g., about 1 second, and both valves 40B and 42A are closed earlier by as much as approximately such a time. The predetermined time t is preset within the aforementioned range based on an inspecting gas flow rate. Therefore, the main control unit 44 can make both sides of the valves 40A and 42A be closed after the predetermined time t is elapsed from the point when flowing a processing gas for inspection, without receiving an instruction of the completion of the measurement from the flow rate measurement control unit 62.

Thereafter, processes are carried out in an order of steps S10, S11, S13, and the like. Here, step S12 (see FIG. 4B) is substituted by a prior step S9-1.

As mentioned above, by closing the valves earlier in both sides of the flow rate controller by as much as a time appropriate for the calculation, an abnormal pressure rising inside the line system can be prevented, to thereby prevent a generation of leak or the like.

Second Embodiment

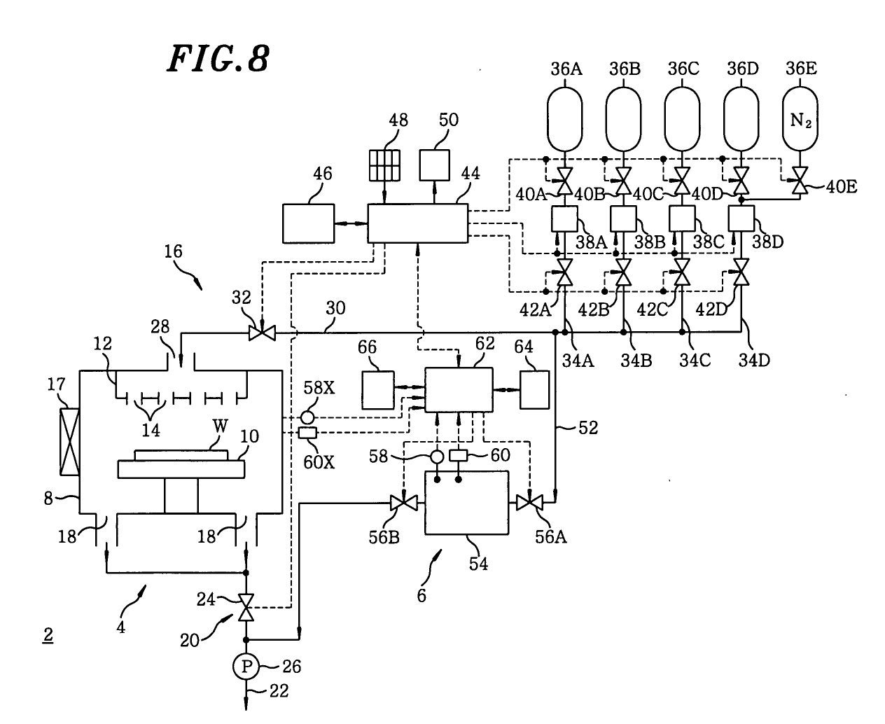

The present embodiment relates to a system in which the number of flow rate controllers is reduced. FIG. 8 is a block diagram for showing a semiconductor processing system including a processing apparatus and a flow rate measuring unit, in accordance with a second embodiment of the present invention. As shown in FIG. 8, a flow rate controller 38D for flowing a processing gas from a gas source 36D is also used as a flow rate controller for controlling an N₂ gas flow rate of a nonreactive gas. By switching from upstream valves 40D to 40E or vice versa, either the gas source 36D or an N₂ gas source 36E is selected.

In case where the flow rate controller 38D is inspected in such a semiconductor processing system, there may be an N₂ gas left in the flow rate controller 38D before flowing the processing gas from the gas source 36D, resulting in a slightly inaccurate measurement of a gas flow rate when inspecting. Therefore, before flowing the processing gas into the flow rate controller 38D, a valve 42D in a downstream side thereof is opened to exhaust the flow rate controller 38D to vacuum (both of the upstream valves 40D and 40E are closed), thereby discharging the residual N₂ gas therefrom.

As described above, by flowing the processing gas after discharging the nonreactive gas remaining in the flow rate controller by exhausting the controller to vacuum, wherein the flow rate controller is used to control the gas flow rate of the nonreactive gas as well as that of the processing gas, it is possible to obtain a more accurate calculation result.

Third Embodiment

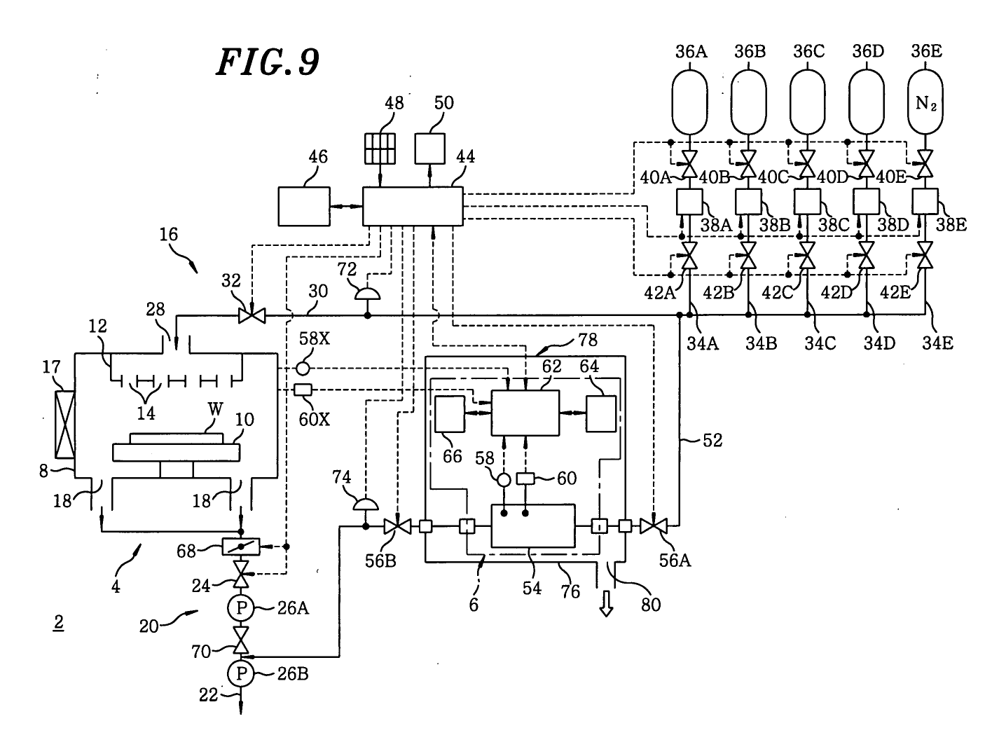

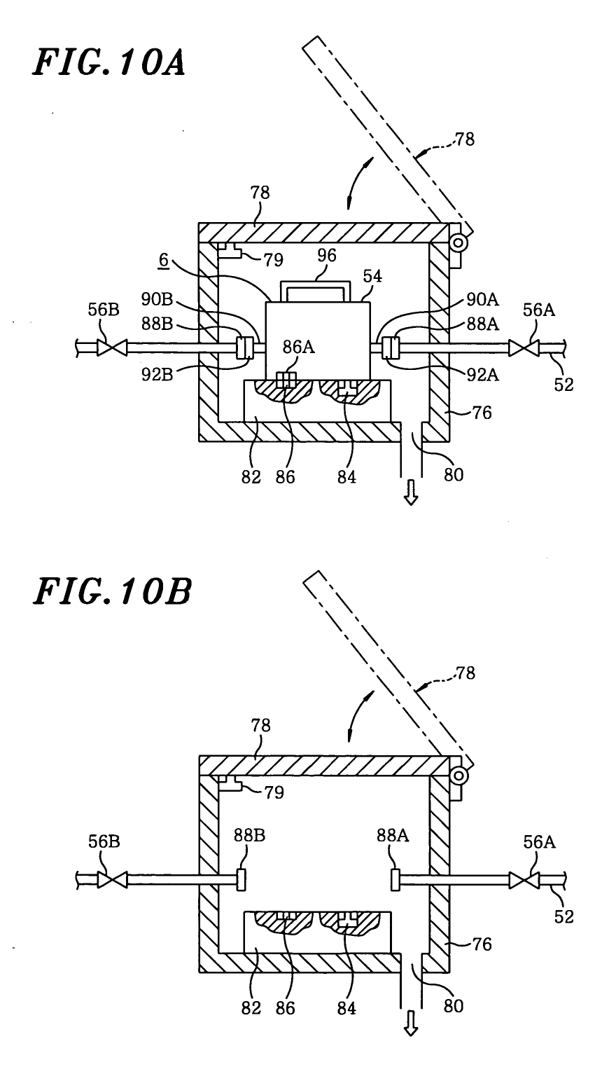

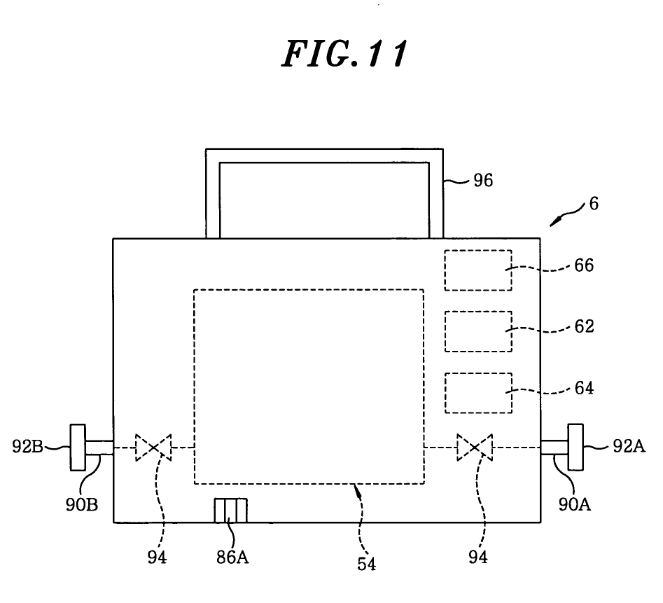

In this embodiment, it is configured such that a flow rate measuring device 6 can be attached and detached itself to and from a bypass line 52, and one flow rate measuring device 6 can be used for another processing system, as well. FIG. 9 is a block diagram for showing a semiconductor processing system including a processing apparatus and a flow rate measuring unit, in accordance with a third embodiment of the present invention. FIGS. 10A and 10B are block diagrams for showing a flow rate measuring unit and a housing accommodating therein same in the system described in FIG. 9, respectively. FIG. 11 is a schematic block diagram for showing an outer appearance of the flow rate measuring unit in the system described in FIG. 9.

As shown in FIG. 9, a pressure control valve 68 having, e.g., a butterfly valve, is installed in an upstream side of an exhaust valve 24, in a gas exhaust line system 20. In a gas exhaust unit connected to the gas exhaust line system 20, a turbo molecular pump 26A and a dry pump 26B are installed in an upstream and a downstream side thereof, respectively. A separation valve 70 is installed at an immediate downstream side of the turbo molecular pump 26A, and a downstream side of the bypass line 52 is connected to the gas unit at a position located between the separation valve 70 and the dry pump 26B. A first pressure gauge 72 is disposed in an upstream side of a supply valve 32 on a gas supply line 30. A second pressure gauge 74 is disposed in a downstream side of the downstream valve 56B on the bypass line 52. Respective detection values of the pressure gauges 72 and 74 are inputted into the main control unit 44.

Meanwhile, on the bypass line 52, a box shaped-housing 76 made of, e.g., aluminum, is disposed. As shown in FIGS. 10A and 10B, the whole flow rate measuring device 6 is accommodated in the housing 76, and it can be attached thereto and detached therefrom. On a ceiling of the housing 76, an opening/closing lid 78 capable of being opened and closed is equipped for opening the inside thereof. Further, on the ceiling of the housing 76, a first switch 79 having, e.g., a pressure switch is installed to detect an opening/closing state of the opening/closing lid 78.

On one side of a bottom part of the housing 76, a gas exhaust port 80 for exhausting the inside thereof is installed. The gas exhaust port 80 is connected to a factory exhaust system or the like and the inside of the housing 76 is exhausted all the time. On the bottom part of the inside the housing 76, a supporter 82 for mounting thereon the flow rate measuring device 6 is placed. The flow rate measuring device 6 is mounted and maintained on the supporter 82. On a top surface of the supporter 82, a second switch 84 having, e.g., a pressure switch is placed to detect the presence of the flow rate measuring device 6. Further, an electric joint 86 electrically connected with the main control unit 44 is disposed on the top surface of the supporter 82. Respective detection signals from the first and the second switch 79 and 84 are sent to the main control unit 44.

Inlet and outlet ends of the bypass line 52 are inserted into the housing 76. Self-sealing connect couplers 88A and 88B are attached to the inlet and outlet ends, respectively. Meanwhile, as shown in FIG. 10A, auxiliary gas lines 90A and 90B are horizontally extended from the inspection vessel 54 of the flow rate measuring device 6. To ends of the auxiliary gas lines 90A and 90B, there are attached self-sealing connect couplers 92A and 92B, which can be quickly connected to the self-sealing connect couplers 88A and 88B, respectively. In each of the auxiliary gas lines 90A and 90B, there is installed an air operation valve 94 that is operated by a compression air (not shown) (see FIG. 11). The air operation valve 94 is opened and closed by an instruction from the main control unit 44, as required.

On a bottom surface of the flow rate measuring device 6, the electric joint 86A connected electrically to the electric joint 86 on the supporter 82 is placed. A grip 96 for use in carrying the whole apparatus 6 is equipped in an upper part of the flow rate measuring device 6. Further, FIG. 10B describes a shape of the housing 76 without including therein the flow rate measuring device 6.

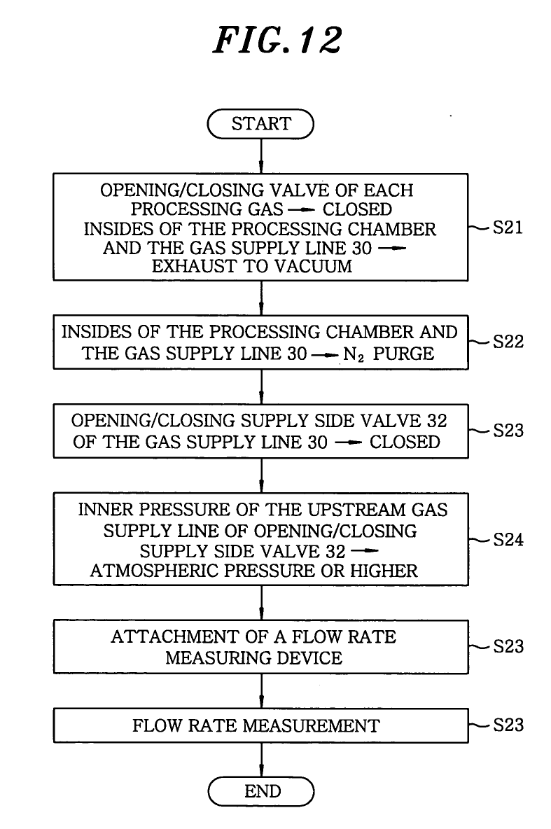

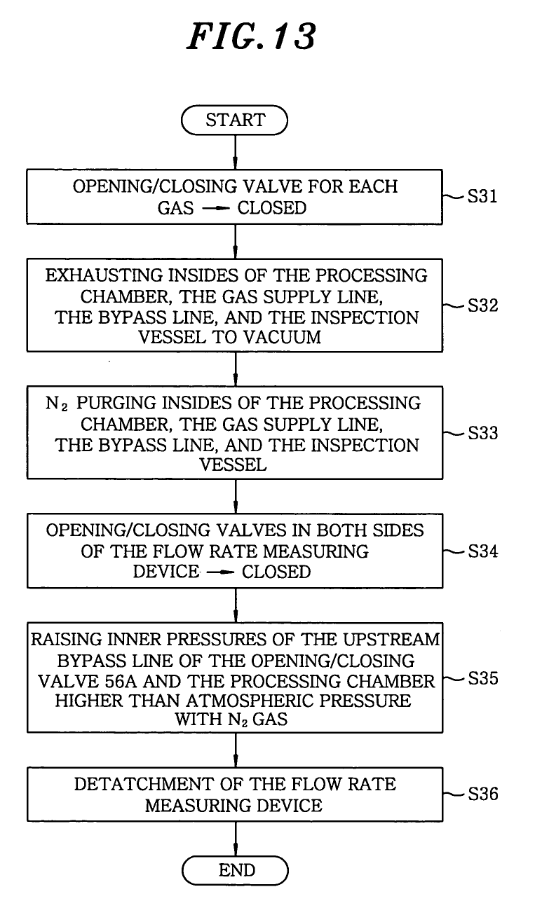

FIG. 12 is a flowchart for showing an attachment of the flow rate measuring unit and a measured flow rate thereof, in the system shown in FIG. 9. FIG. 13 is a flowchart for showing a detachment flow of the flow rate measuring device, in the system described in FIG. 9. Hereinafter, an attachment and a detachment of the flow rate measuring device will be explained with reference to FIGS. 12 and 13.

First, before explaining a total flow, an interlocking relationship between respective detection results of the first and the second switch 79 and 84 and a required valve will be discussed. Further, the valves 56A and 56B are controlled by the main control unit 44.

In case where the opening/closing lid 78 is opened and the flow rate measuring device 6 is present inside of the housing 76, the valves 56A and 56B are closed, and the valves 40A to 40E and 42A to 42E, which are of a stopper of each gas, are interlocked to maintain the closed state to secure the safety of the operator from a gas leak due to an opening of the opening/closing lid 78.

In case where the opening/closing lid 78 is opened and the flow rate measuring device 6 is absent therein, both of the valves 56A and 56B are closed, and the valves 40A to 40E and 42A to 42E, each of which is of a stopper of a gas, are interlocked to maintain the closed state to secure the safety of the operator from a gas leak due to an opening of the opening/closing lid 78.

In case where the opening/closing lid 78 is closed and the flow rate measuring device 6 is present therein, both of the valves 56A and 56B are opened, and the valves 40A to 40E and 42A to 42E, each of which is of a stopper of a gas, are interlocked to maintain an open state. As a result, an actual gas flow rate can be measured.

In case where the opening/closing lid 78 is closed and the flow rate measuring device 6 is absent therein, both of the valves 56A and 56B are closed, and the valves 40A to 40E and 42A to 42E, each of which is of a stopper of a gas, are interlocked to be opened. As a result, actually, a predetermined process can be performed by flowing a gas into the processing chamber 8.

Meanwhile, an attachment and a measurement of the flow rate measuring device 6 are performed as shown in FIG. 12. Further, during operations to be described below, both pumps 26A and 26B are operated and exhausted to vacuum all the time.

First, it is confirmed that the valves 40A to 40E and 42A to 42E, each of which is of a stopper of a gas, are closed. Then, an inside of the gas supply line 30 in addition to that of the processing chamber 8 are exhausted to vacuum to discharge a residual gas therefrom (step S21). After that, an N₂ gas is introduced into the processing gas 8 and the gas supply line 30 to purge the insides thereof (step S22).

Next, a supply valve of the gas supply line 30 is closed (step S23). In such a state, an inner pressure of the gas supply line 30 in an upstream side of the supply valve 32 becomes a little higher than an atmospheric pressure, i.e., a positive pressure state (step S24). Accordingly, even though the valve 56A is opened when attaching the apparatus, the air possibly containing particles and the like is not introduced into the bypass line 52.

Then, as shown in FIG. 10A, the opening/closing lid 78 of the housing 76 is opened to accommodate and equip therein a portable flow rate measuring device 6 for measuring a flow rate, and then, closed (step S25). Here, the gas exhaust valve 24 is closed to protect the turbo molecular pump 26A. Further, the downstream valve 56B of the bypass line 52 is opened, and it is confirmed that the second pressure gauge 74 provided in the bypass line 52 reads a pressure lowered to a predetermined pressure. By this, leak is checked and a normal state is confirmed.

Subsequently, the same flow rate measurement as in the first embodiment is performed on the flow rate measuring device 6 by flowing an actual gas thereto (step S26).

As shown in FIG. 13, a detachment of the flow rate measuring device 6 is carried out. During an operation to be described below, both pumps 26A and 26B are operated to exhaust to vacuum all the time.

First, it is confirmed that the valves 40A to 40E and 42A to 42E, each of which is of a stopper of a gas, are closed (step S31). Then, insides of the processing chamber 8, the gas supply line 30, the bypass line 52 and the inspection vessel 54 are exhausted to vacuum (step S32). Further, the N₂ gas is introduced to purge the insides thereof (step S33). Then, the valves 56A and 56B in both sides of the flow rate measuring device 6 and the air operation valves 94 are closed (step S34). After that, each of the inner pressures of the bypass line 52 and the processing chamber 8 in an upstream side of the valve 56A becomes higher than an atmospheric pressure with the N₂ gas (step S35).

Next, the opening/closing lid 78 of the housing 76 is opened to detach the flow rate measuring device 6 attached thereto to take it out therefrom, and then, closed (step S36). The detached flow rate measuring device 6 may be also used for another semiconductor processing system, if necessary.

As mentioned above, since the flow rate measuring device 6 can be detached and used in multiple processing systems, only a single flow rate measuring unit is needed. Further, a flow rate error due to an individual variation of a flow rate measuring can be prevented, so that process reproducibility in processing systems can be improved.

Next, a measurement reference correction of the flow rate measuring device 6 will be discussed. Further, a correction operation to be explained below may be applied to any of the semiconductor processing systems shown in FIGS. 1, 8, and 9. Still further, the correction operation may be applied to the aforementioned inspecting method of the flow rate controller in which the processing chamber 8 is used as an inspection vessel instead of the inspection vessel 54. In this case, for performing the aforementioned inspecting method on the flow rate controller, the pressure gauge 58× and the temperature gauge 60× are installed in the processing chamber 8, as shown in FIGS. 1, 8, and 9. Further, in the main control unit 44 and the flow rate measurement control unit 62, programs for performing the aforementioned inspecting method on the flow rate controller by using the processing chamber 8 as the inspection vessel are installed.

Generally, by using the flow rate controllers 38A to 38E such as a mass flow controller, a flow rate control can be performed on a minor amount of gas with a high accuracy. However, an actual gas flow rate may be changed from a set flow rate due to aging and the like. As a result, a flow rate stability is checked regularly or irregularly as mentioned above, and an offset process, i.e., a correction, is carried out such that the set flow rate coincides with the actually measured flow rate.

On a factory shipment of a flow rate controller, a flow rate is set as a reference on shipping. However, in a factory shipment step, a flow rate measurement for a practically used gas species is not performed at the moment. Thus, in case where a flow rate controller is actually equipped and operated inside a processing apparatus and a correction process is performed regularly or irregularly, a difference between the actually measured flow rate and the reference flow rate set on shipping may be larger than a tolerance value. Further, by the above-described correction method, aging cannot be recognized in an actual operating state after equipping the flow rate measuring device in the processing apparatus.

For resolving such a problem, instead of the factory-set flow rate, an initially measured reference flow rate obtained when the flow rate controller is initially installed in the processing apparatus will be used as a reference for comparison on a correction operation in following explanation. Namely, an actually measured flow rate produced by initially measuring a flow rate by way of flowing a gas to be actually used is stored in the flow rate controller, and is used as the initially measured reference flow rate, which serves as a reference for a subsequent correction operation. To be more specific, a correction operation is carried out in such a way that the actual flow rate measured first at a predetermined set flow rate is used as the initially measured reference flow rate. After that, the difference between an actual flow rate subsequently measured at the predetermined set flow rate and the initially measured reference flow rate is calculated. If an error falls outside a predetermined range and it is determined to be abnormal, operation of the processing apparatus 4 is stopped.

(Initial Flow Rate Correction Operation)

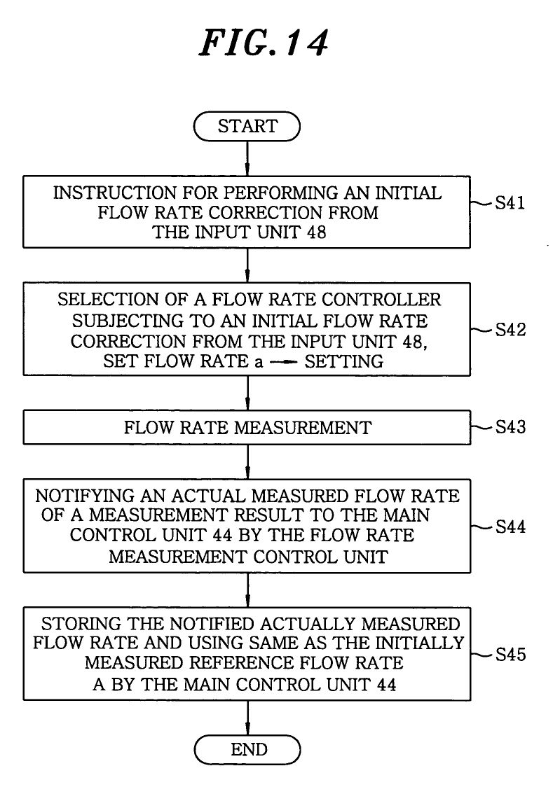

FIG. 14 is a flowchart for explaining an initial flow rate correction operation for obtaining an initially measured reference flow rate.

If a flow rate controller shipped from a factory is equipped in a processing apparatus, the initial flow rate correction operation is carried out. Further, the initial flow rate correction operation may be performed in a case where the flow rate controller is employed to be used for a gas different from the gas used so far or in a case where the flow rate controller has been used without a flow rate correction for a predetermined time.

First, an instruction for performing an initial flow rate correction is inputted into a main control unit 44 from an input unit 48 (step S41). Further, a flow rate controller for correcting an initial flow rate is selected and the information on the selection is also inputted into the main control unit 44 from the input unit 48, and at this time, a set flow rate a is set at a predetermined flow rate (step S42). Still further, with respect to a flow rate controller selection, it can be configured such that a gas line (branch line) to which the selected flow rate controller is disposed is selected instead of the controller itself and information thereof is inputted.

Next, a flow rate measurement is carried out by actually flowing a gas (step S43). At this time, a performing order of the flow rate measurement is the same as that in the first embodiment shown in FIG. 1. If an actually measured flow rate b is obtained, such a measurement result is notified to the main control unit 44 by the flow rate measurement control unit 62 (step S44).

Then, the actually measured flow rate b is stored in, e.g., a memory 46 and defined as an initially measured reference flow rate A by the main control unit 44 that received the measurement result (step S45). In this case, the actually measured flow rate b and the set flow rate a are displayed in a display unit 50 and, the actual flow rate b may be employed as the initially measured reference flow rate A, by inputting an instruction that the measurement result is adopted as a data for an initial correction by an operator. Further, a reference measurement flow rate, which becomes a reference when giving an instruction to the flow rate controller corresponding to a set flow rate, is stored in the memory 46. Since a flow rate change due to aging is absorbed by the reference measurement flow rate, a proper modification or correction is made by the correction operation, as mentioned below. In the factory shipment step, the flow rate set on shipping is stored as the reference measurement flow rate.

Further, in conventional processes, the processes are sequentially progressed by the main control unit 44 with reference to a program in which a process pressure, a temperature, a gas species, a gas flow rate, and the like are pre-stored, i.e., a recipe. At this time, in case of flowing a gas, a gas flow rate is controlled at a set flow rate stored in the recipe, by the main control unit 44. The aforementioned initial correction operation is carried out with a specific set flow rate for each of the flow rate controllers 38A to 38E.

(Conventional Flow Rate Correction Calculation)

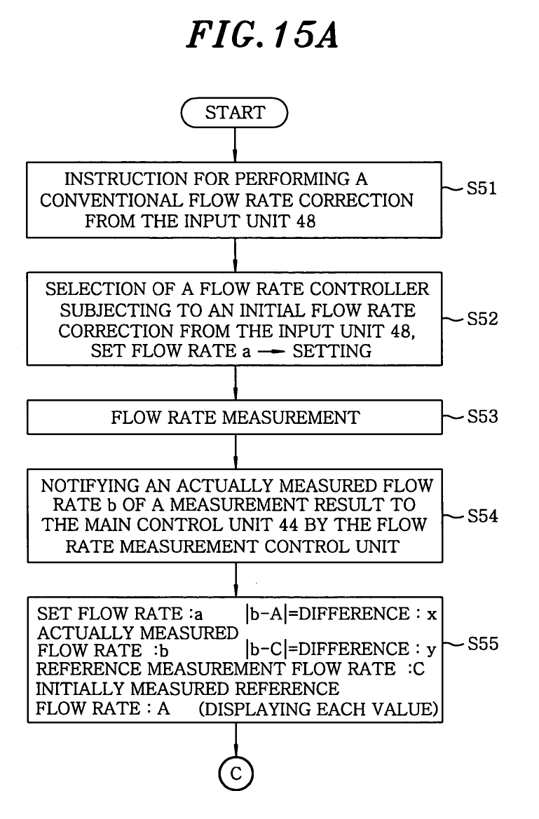

As described above, if the initially measured reference flow rate A is determined, it is employed as a reference measurement flow rate C first, and a process on an actual product wafer is performed continuously. Further, a conventional flow rate correction operation is regularly or irregularly performed on a flow rate controller to correct a flow rate error, which is generated due to aging of the flow rate controller. FIGS. 15A and 15B are flowcharts for explaining the conventional flow rate correction operation after determining a subsequent reference measurement flow rate.

When the conventional flow rate correction calculation is to be performed, an instruction for performing the conventional correction calculation is inputted from the input unit 48 (step S51). Further, a flow rate controller (a branch line) subjecting to the conventional flow rate correction is selected from the input unit 48, and the set flow rate a is set (step S52).

Subsequently, a flow rate measurement is carried out by flowing a gas (step S53). At this time, a performing order of the flow rate measurement is the same as that in the first embodiment shown in FIG. 1. Further, if the actually measured flow rate b is obtained, the measurement result is given to the main control unit 44 by the flow rate measurement control unit 62 (step S54).

By the main control unit 44 that received the measurement result, the set flow rate a, the actually measured flow rate b corresponding to the measurement result, the current reference measurement flow rate C, the initially measured reference flow rate A, a difference x (absolute value) between the actually measured flow rate b and the initially measured reference flow rate A, and a difference y (absolute value) between the actual flow rate b and the current reference measurement flow rate C are stored. Further, these values are displayed in the display unit 50 for confirmation of the operator (step S55).

Next, the difference x is compared with a predetermined range V by the main control unit 44. As a result, if the difference x is larger than the predetermined range V (in case of YES in step S56), it is determined to be abnormal since aging effect has made the flow rate much larger than the initially measured reference flow rate A. Further, a message is displayed in the display unit 50 as a warning signal E1 (step S57). Here, the warning signal E1 means that a serious error has occurred.

Further, a full operation of the processing apparatus 4 is stopped by the main control unit 44 (step S58), so that a process on the product wafer is not performed in an unstable state of a gas flow rate. Therefore, the conventional correction operation is terminated. Here, the predetermined range V is, e.g., about 5% for the set flow rate a.

Further, in case of NO in step S56, the difference value y for the current reference measurement flow rate C obtained from the conventional correction operation performed right before is compared with a predetermined range M. As a result, if the difference y is larger than the predetermined range M (in case of YES in step S59), a warning signal E2 is displayed in the display unit 50 (step S60). This means that the difference y between the actually measured flow rate b and the current measured flow rate C, which was obtained by the conventional correction operation, becomes significantly large, i.e., aging during this time is distinguishable. The warning signal E2 is not such a significant error to terminate the operation of the processing apparatus 4 itself as the case for the warning signal E1, but an instruction thereof is displayed in the display unit 50 to call the attention of the operator. Further, the conventional correction operation is completed. Here, the predetermined range M is, e.g., about 2% for the reference measurement flow rate.

Further, in case of NO in step S59, the operator is asked whether or not the actually measured flow rate b will be employed as a new reference measurement flow rate C (step S61). In case of YES, it can be assumed that the flow rate controller undergoes a change within a normal aging range. Accordingly, a correction is carried out in such a manner that the current reference measurement flow rate C is replaced with the actually measured flow rate b (step S62). By doing this, the conventional correction operation is completed. Further, all the reference measurement flows measured before, the number of flow rate corrections, and the like may be stored in the memory 46. In case of NO in each of the determination steps S56, S59, and S61, it is natural that the reference measurement flow rate is not corrected and remains as it is.

The aforementioned conventional correction operation is performed on all the flow rate controllers 38A to 38E. By such an operation, aging in each of the flow rate controllers is checked by using the initially measured reference flow rate A as a reference when performing the conventional flow rate correction operation. Therefore, an aging level can be properly determined.

In the aforementioned explanation, in case of performing the correction operation, a flow rate measurement is carried out at a predetermined set flow rate a. However, in case when actually using the flow rate controller, one or more additional set flows may be employed depending on a recipe. Accordingly, a flow rate stability of the flow rate controller may be checked at the additional one or more flow rates over a full range, e.g., four set flow rates a of 25%, 50%, 75%, and 100%. Further, the set point of the flow rate is not limited to the four but, e.g., 10 points may be employed.

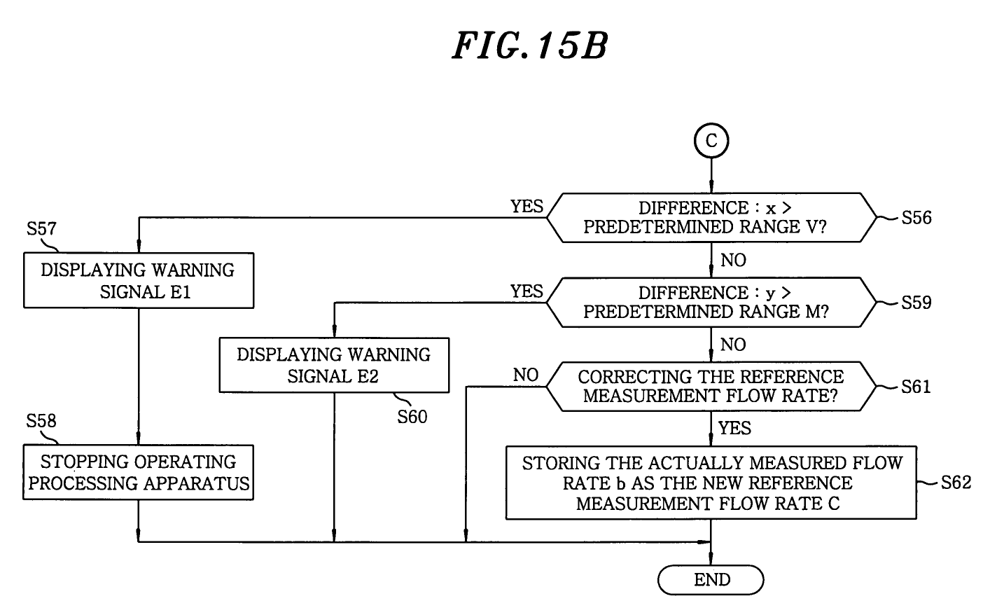

In the aforementioned explanation, by the initial flow rate correction operation and the conventional flow rate correction operation, a characteristic curve for showing a relationship between the set flow rate and the actually measured flow rate can be obtained as shown in FIG. 16. In FIG. 16, a curve A1 is a reference characteristic curve obtained when performing an initial flow rate correction operation and other curves b1 to b4 show examples of reference characteristic curves obtained when performing a conventional flow rate correction operation four times.

In this case, an error (offset) shifted from the initial reference characteristic curve A1 varies due to aging, so that each curve undergoes a change, e.g., each line being shifted parallel to each other. Here, a maximum value Z of an offset amount from the initial reference characteristic curve A1 is given as an upper or a lowest limit. Further, in case when the offset becomes larger than Z, it is determined to be abnormal, so that an operation of the processing apparatus itself may be stopped. Further, the maximum value Z corresponds to the predetermined range V explained in FIG. 15B.

Meanwhile, it is preferable that the conventional flow rate correction operation is pre-programmed at additional flow rates over a full range of the flow rate controller, and is set in a fully automated manner by the main control unit 44 such that the flow rate need not be inputted each time by the operator. Accordingly, a conventional flow rate correction operation can be performed in a short time without bothering the operator.

As described above, a pressure rising rate is measured by flowing a gas into the inspection vessel 54 at a predetermined set flow rate. In this case, the pressure gauge 58 may detect the pressure not continuously but intermittently at a predetermined time interval, i.e., a predetermined sampling interval. If the sampling interval is fixed, the pressure rising rate may not be detected at a proper interval in case where a gas set flow rate, an end pressure after exhaustion to vacuum when correcting, or a waiting time for stabilizing a gas is different. Thus, as a first operation, a time needed for reaching a target pressure by actually flowing the gas is measured in an actual correction operation. By this, an operation for obtaining a proper sampling interval, i.e., a sampling interval determination operation is performed. After that, in an actual measurement operation for measuring a rising pressure while actually flowing a gas again after exhausting to vacuum, the sampling interval determined by the aforementioned operation is used.

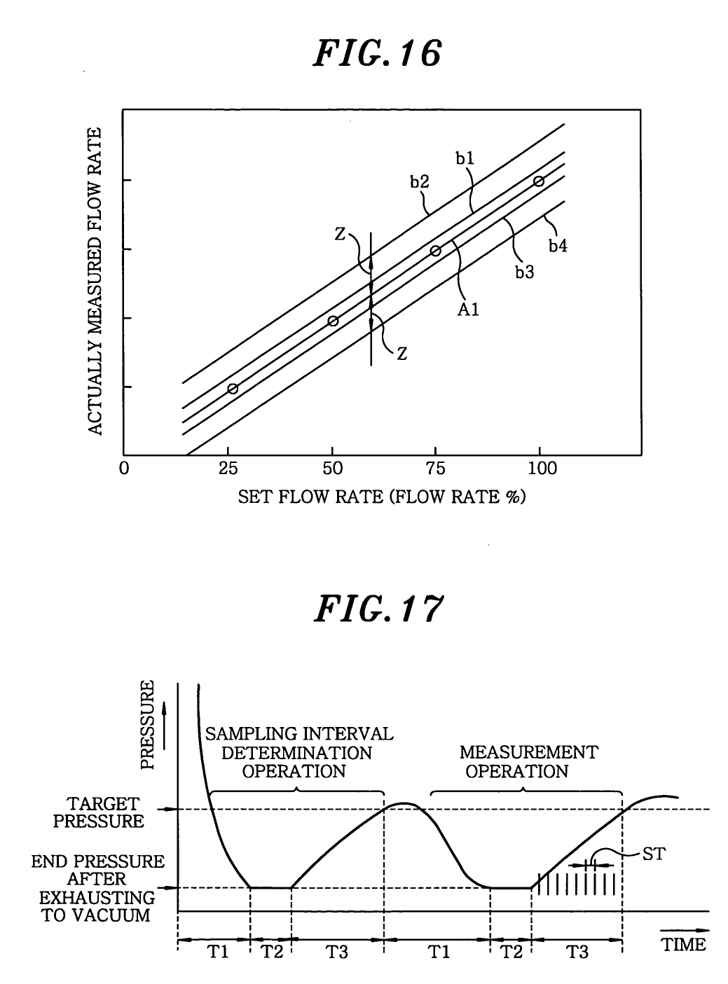

FIG. 17 is a time chart for showing a case that the sampling interval determination operation and the actual measurement operation are sequentially performed. In FIG. 17, T1 represents a time needed for reaching an end pressure after exhausting to vacuum, T2 is a waiting time for stabilizing a gas pressure, and T3 is a time needed for reaching a target pressure. As shown in FIG. 17, first, the time T3 needed for reaching a target pressure is obtained by performing the sampling interval determination operation. In case of performing a sampling operation several times, e.g., ten times, the total time is divided by “10” to thereby calculate a sampling interval ST. Further, in a subsequent actual measurement operation, by flowing a gas again after exhausting an inside of the inspection vessel 54 to vacuum, a rising pressure is detected by using the sampling interval ST.

However, in case of performing the two operations every time, it takes too much time to perform the conventional flow rate correction. Therefore, if respective set conditions when performing the conventional flow rate correction, i.e., a gas set flow rate, a vacuum exhaust end pressure on correcting, a waiting time for stabilizing a gas, and the like are the same with those in the conventional correction operation performed before, which were stored in the memory 46, the sampling interval determination operation is not performed and the actual measurement operation is directly carried out. At this time, the prior sampling interval ST under the same set conditions will be used as the sampling interval ST. In this way, the time needed to perform the conventional flow rate correction can be substantially reduced.

Further, the aforementioned flow rate correction operation may be applied to any equipment as long as a zero point is adjusted by obtaining an offset, and for example, may be applied to the pressure gauge.

In each of the aforementioned embodiments, a single wafer processing apparatus was explained as an example of the processing apparatus. However, the present invention may be applied to any processing apparatus for performing a vacuum process, an atmospheric process, or the like as long as a processing gas is employed. Further, the present invention may be applied to a batch type processing apparatus in which a plurality of wafers is processed at a time as well as a single wafer. Further, in each of the embodiments, the semiconductor wafer was explained as an example of the substrate to be processed, but it is not limited thereto. The present invention may be employed in a glass substrate, an LCD substrate, and the like.

While the invention has been shown and described with respect to the preferred embodiments, it will be understood by those skilled in the art that various changes and modifications may be made without departing from the spirit and scope of the invention as defined in the following claims.

1. A semiconductor processing system, comprising:
a processing chamber for accommodating therein a substrate to be processed;
a gas exhaust unit, connected to the processing chamber through a gas exhaust line, for exhausting the processing chamber;
a gas supply unit, connected to the processing chamber through a gas supply line, for supplying a processing gas into the processing chamber;
a flow rate controller, disposed on the gas supply line, for controlling a flow rate of the processing gas;
a flow rate measuring unit for inspecting the flow rate controller; and
a control unit for controlling the processing system,
wherein the flow rate measuring unit includes:
an inspection vessel having a predetermined volume and placed on a gas bypass line connecting the gas supply line with the gas exhaust line to bypass the processing chamber;
a pressure gauge for detecting an inner pressure of the inspection vessel; and
a flow rate calculation unit for obtaining a gas flow rate of the flow rate controller based on a rising rate of a detection value from the pressure gauge, and
wherein the control unit is configured to purge the inspection vessel by flowing a nonreactive gas to the inspection vessel before or after flowing the processing gas thereto.

2. The semiconductor processing system of claim 1, wherein the control unit is configured to stop supplying the processing gas to the flow rate measuring unit in advance by as much as a calculation time of the flow rate calculation unit.

3. The semiconductor processing system of claim 1, wherein the control unit stores a correction coefficient of individual variation depending on an individual variation of the flow rate controller and receives a calculation result from the flow rate calculation unit to thereby compensate the calculation result by using the correction coefficient of individual variation.

4. The semiconductor processing system of claim 1, wherein the control unit stores a volume correction coefficient for each flow rate controller, and the flow rate calculation unit calculates the gas flow rate taking the volume correction coefficient into consideration.

5. The semiconductor processing system of claim 1, wherein the flow rate controller is placed to be used for the processing gas and the nonreactive gas together, and the control unit is configured to flow the processing gas after exhausting a residual nonreactive gas in case when the nonreactive gas remains in the flow rate controller.

6. The semiconductor processing system of claim 1, wherein the processing system further includes one or more flow rate controllers corresponding to one or more process gases, and the control unit is configured to inspect said the flow rate controller and said one or more flow rate controllers in a sequential order by sequentially flowing the processing gas and the process gases according to the sequential order.

7. The semiconductor processing system of claim 1, wherein the nonreactive gas is an N₂ gas.

8. The semiconductor processing system of claim 1, wherein the flow rate measuring unit includes a flow rate measuring device that can be attached and detached to and from the bypass line to thereby be used for additional processing systems, as well.

9. The semiconductor processing system of claim 1, wherein the flow rate measuring device has a lid that can be opened and closed, and is accommodated in a housing whose inner atmosphere is exhausted.

10. The semiconductor processing system of claim 9, wherein a first switch for detecting an opened/closed state of the lid and a second switch for detecting a presence of the flow rate measuring device are installed in the housing, and the control unit determines whether or not the processing gas will be supplied into the inspection vessel based on detection results obtained by the first and the second switch.

11. The semiconductor processing system of claim 1, wherein the control unit performs a correction operation by using a flow rate actually measured by the flow rate control unit initially obtained for a predetermined set flow rate as an initially measured reference flow rate, and then, calculates the difference between an actual flow rate subsequently measured by the flow rate measuring unit at the predetermined set flow rate and the initially measured reference flow rate, so that it is determined to be abnormal in case where the difference falls outside a predetermined range.

12. The semiconductor processing system of claim 11, wherein the control unit displays in a display unit a warning instruction about the abnormal state in case when it is determined to be abnormal.

13. The semiconductor processing system of claim 11, wherein in case when the difference falls outside the predetermined range, the control unit displays in a display unit an instruction thereof.

14. The semiconductor processing system of claim 11, wherein the control unit performs the correction operation multiple times for multiple set flow rates to obtain a multiple number of actually measured flow rates serving as reference measurement flow rates, and controls the flow rate controller based on the reference measurement flow rates when performing an actual process.

15. The semiconductor processing system of claim 11, wherein the control unit declares an abnormal state when a reference characteristic line produced from actually measured flow rates obtained for various set flow rates is shifted beyond a predetermined range from an initial reference characteristic line produced from initial reference measurement flow rates obtained for the set flow rates.

16. An inspecting method of a flow rate controller in a semiconductor processing system having a processing chamber for accommodating therein a substrate to be processed; a gas exhaust unit, connected to the processing chamber through a gas exhaust line, for exhausting the processing chamber; a gas supply unit, connected to the processing chamber through a gas supply line, for supplying a processing gas into the processing chamber; and a flow rate controller, disposed on the gas supply line, for controlling a flow rate of the processing gas, the method comprising the steps of:
flowing the processing gas, whose flow rate is controlled by the flow rate controller, to an inspection vessel having a predetermined volume while a gas exhaust side thereof is closed, wherein the inspection vessel is disposed on a gas bypass line connecting the gas supply line with the gas exhaust line to bypass the processing chamber;
detecting an inner pressure of the inspection vessel;
obtaining a gas flow rate of the flow rate controller by a calculation based on a rising rate of a detected pressure; and
performing a purge process on the inspection vessel by flowing to the inspection vessel a nonreactive gas before or after flowing the processing gas thereto.

17. The inspecting method of claim 16, wherein in the step of flowing the processing gas, it is configured such that supplying the processing gas is stopped in advance by as much as a calculation time of the gas flow rate.

18. The inspecting method of claim 16, wherein a calculation result obtained by the calculation is compensated by using a correction coefficient of individual variation depending on an individual variation of the flow rate controller.

19. The inspecting method of claim 16, wherein the gas flow rate is obtained by taking a volume correction coefficient for the flow rate controller into consideration, when calculating the gas flow rate by a calculation.

20. The inspecting method of claim 16, wherein the flow rate controller is placed to be used for the processing gas as well as the nonreactive gas, and
wherein the method further comprises the step of exhausting a residual nonreactive gas to vacuum before flowing the processing gas, in case when the nonreactive gas remains in the flow rate controller.

21. The inspecting method of claim 16, wherein the processing system further includes one or more flow rate controllers corresponding to one or more process gases, and
wherein the method further comprises the step of sequentially flowing the processing gas and the process gases such that said flow rate controller and said one or more flow rate controllers are inspected in a sequential order.

22. A semiconductor processing system, comprising:
a processing chamber for accommodating therein a substrate to be processed;
a gas exhaust unit, connected to the processing chamber through a gas exhaust line, for exhausting the processing chamber;
a gas supply unit, connected to the processing chamber through a gas supply line, for supplying a processing gas into the processing chamber;
a flow rate controller, disposed on the gas supply line, for controlling a flow rate of the processing gas;
a pressure gauge for detecting an inner pressure of the processing chamber;
a flow rate calculation unit for obtaining a gas flow rate of the flow rate controller based on a rising rate of a detection value from the pressure gauge; and
a control unit for controlling the processing system,
wherein the control unit performs a correction operation by using an actually measured flow rate initially obtained by the flow rate calculation unit for a predetermined set flow rate as an initially measured reference flow rate, subsequently, calculates the difference between an actual flow rate subsequently measured by the flow rate calculation unit for the predetermined set flow rate and the initially measured reference flow rate, and declares an abnormal state where the difference falls outside a predetermined range.

23. The semiconductor processing system of claim 22, wherein the control unit displays in a display unit an instruction of the abnormal state in case when it is determined to be abnormal.

24. The semiconductor processing system of claim 22, wherein in case when the error falls outside the predetermined range, the control unit displays in a display unit a warning instruction thereof.

25. The semiconductor processing system of claim 22, wherein the control unit performs the correction operation multiple times for multiple set flow rates to obtain a multiple number of actually measured flow rates serving as reference measurement flow rates, and controls the flow rate controller based on the reference measurement flow rates when performing an actual process.

26. The semiconductor processing system of claim 22, wherein the control unit declares an abnormal state when a reference characteristic line produced from actually measured flow rates obtained for various set flow rates is shifted beyond a predetermined range from an initial reference characteristic line produced from initial reference measurement flow rates obtained for the set flow rates.
